(19) United States
(12) Patent Application Publication
(10) Pub. No.: US 2010/0078669 A1
(43) Pub. Date: Apr. 1, 2010

(54) LIGHT EMITTING DEVICE AND LEAD FRAME FOR THE SAME

(75) Inventors: Yu-Jeong CHO, Ansan-si (KR); Kyung-Nam Kim, Ansan-si (KR); Kwang-Yong Oh, Ansan-si (KR)

Correspondence Address: H.C. PARK & ASSOCIATES, PLC, 8500 LEESBURG PIKE, SUITE 7500, VIENNA, VA, 22182, US

(73) Assignee: SEOUL SEMICONDUCTOR CO., LTD., Seoul (KR)

(21) Appl. No.: 12/569,208

(22) Filed: Sep. 29, 2009

(30) Foreign Application Priority Data
Sep. 29, 2008 (KR) 2008-0095458
Jul. 7, 2009 (KR) 2009-0061691

(51) Int. Cl. H01L 33/00; H01L 23/495

(52) U.S. Cl. 257/98; 257/676; 257/99; 257/E23.031; 257/E33.059; 257/E33.061; 257/E33.066

(57) ABSTRACT

An LED according to the present invention includes a light-emitting chip emitting light, a chip-mounting portion on which the light-emitting chip is mounted, a light-reflecting layer formed on at least a portion of the chip-mounting portion and a gold plating layer formed on at least a portion of the light-reflecting layer, the gold plating layer having a thickness such that the gold plating layer has a different color from a color of gold. The chip-mounting portion may have various shapes and materials. For example, the chip-mounting portion may be a lead terminal, a slug, a printed circuit board, a ceramic substrate, a CNT substrate, etc.

### CROSS REFERENCE TO RELATED APPLICATION

This application claims priority from and the benefit of Korean Patent Application No. 2008-95458, filed on Sep. 29, 2008, and Korean Patent Application No. 2009-61691, filed on Jul. 7, 2009, which are hereby incorporated by references for all purposes as if fully set forth herein.

### BACKGROUND OF THE INVENTION

1. Field of the Invention

Exemplary embodiments of the present invention relate to a light emitting device and a lead frame for the light emitting device or, more particularly, to a light emitting device and a lead frame capable of reducing corrosion while minimizing a reduction in reflectivity.

2. Discussion of the Background

A light-emitting diode (LED) emits light by using electrical power, and has qualities such as high efficiency, long lifespan, low power consumption, being environmentally friendly, etc., as a light source. Therefore, the LED is widely used in various industrial fields.

In general, the LED includes a chip emitting light by using electric power. The chip may be mounted on a chip-mounting portion of a lead frame, slug, or printed circuit board.

According to a conventional LED, the chip-mounting portion is plated with silver (Ag) to improve reflectivity of light. However, the reflectivity of a light-reflecting layer, which is plated with silver (Ag), is gradually deteriorated when the LED is used for an extended period of time, since silver is easily discolored by moisture and heat.

### SUMMARY OF THE INVENTION

Exemplary embodiments of the present invention provide an LED and a lead frame for the LED, which are capable of reducing corrosion while minimizing a reduction in reflectivity.

Additional features of the invention will be set forth in the description which follows, and in part will be apparent from the description, or may be learned by practice of the invention.

An exemplary embodiment of the present invention discloses a light emitting device (LED) comprising a light-emitting chip to emit light; a chip-mounting portion on which the light-emitting chip is disposed; a light-reflecting layer disposed on the chip-mounting portion; and a gold plating layer disposed on the light-reflecting layer, the gold plating layer having a thickness such that the gold plating layer has a different color from a color of gold (Au).

An exemplary embodiment of the present invention also discloses a lead frame comprising a lead terminal; a light-reflecting layer disposed on the lead terminal; and a gold plating layer disposed on the light-reflecting layer, the gold plating layer having a thickness such that the gold plating layer has a different color from a color of gold (Au).

An exemplary embodiment of the present invention also discloses a light emitting device (LED) comprising a light-emitting chip to emit light; a chip-mounting portion on which the light-emitting chip is disposed; a light-reflecting layer disposed on the chip-mounting portion; a gold plating layer disposed on the light-reflecting layer, the gold plating layer having a thickness such that the gold plating layer has a different color from an intrinsic color of gold (Au); and wherein the light-reflecting layer has a higher electrical conductivity and a higher reflectivity than the lead terminal.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plane view illustrating an LED according to an exemplary embodiment of the present invention.

FIG. 2 is a cross-sectional view taken along line I-I′ in FIG. 1.

FIG. 3 is an enlarged view illustrating a lead frame in FIG. 2.

FIG. 4 is a graph showing a relationship between a thickness of a light-reflecting layer including gold (Au) and efficiency.

FIG. 5 is a cross-sectional view illustrating a lead frame according to another exemplary embodiment of the present invention.

FIG. 6 is a cross-sectional view illustrating an LED according to still another exemplary embodiment of the present invention.

FIG. 7 is a cross-sectional view illustrating an LED according to still another exemplary embodiment of the present invention.

FIG. 8 is a cross-sectional view illustrating an LED according to still another exemplary embodiment of the present invention.

FIG. 9 is a cross-sectional view illustrating an LED according to still another exemplary embodiment of the present invention.

FIG. 10 is an enlarged view illustrating the portion ‘A’ in FIG. 9.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

The LED according to the present invention includes a light-emitting chip emitting light, a chip-mounting portion on which the light-emitting chip is mounted, a light-reflecting layer formed on at least a portion of the chip-mounting portion and a gold plating layer formed on at least a portion of the light-reflecting layer, the gold plating layer having a thickness such that the gold plating layer has a different color from a color of gold. The chip-mounting portion may have various shapes and materials. For example, the chip-mounting portion may be a lead terminal, a slug, a printed circuit board, a ceramic substrate, a CNT substrate, etc.

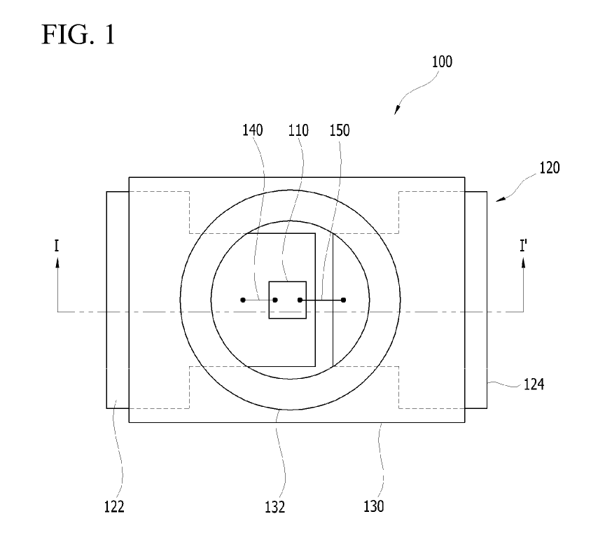

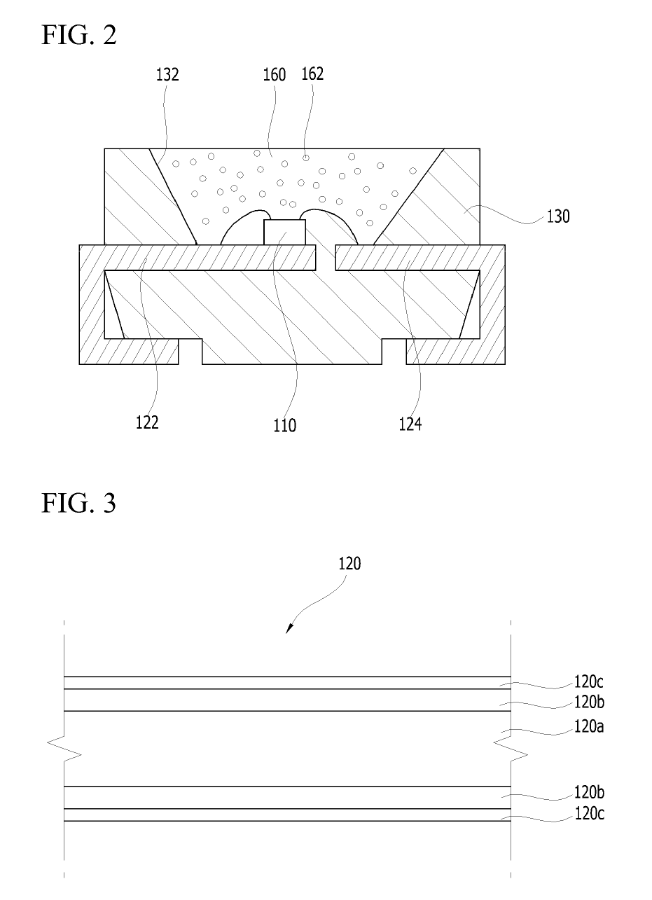

FIG. 1 is a plane view illustrating an LED according to an exemplary embodiment of the present invention. FIG. 2 is a cross-sectional view taken along line I-I′ in FIG. 1, and FIG. 3 is an enlarged view illustrating a lead frame in FIG. 2.

Referring to FIG. 1, FIG. 2 and FIG. 3, a light emitting device (LED) 100 according to an exemplary embodiment of the present invention includes a light-emitting chip 110 emitting light, a lead frame 120 for providing the light-emitting chip 110 with electric power and a housing 130 for fixing the lead frame 120. Additionally, the LED 100 may further include a first conducting wire 140 and a second conducting wire 150 electrically connecting the light-emitting chip 110 to the lead frame 120, and an encapsulant 160 filled in an opening portion 132 of the housing 130.

The light-emitting chip 110 emits light, when the light-emitting chip 110 receives electric power. The light-emitting chip 110 may emit light with a wavelength in a range of infrared and ultraviolet. The light-emitting chip 110 may be, for example, a side-emitting type or a top-emitting type.

The lead frame 120 supports the light-emitting chip 110, and applies external electrical power to the light-emitting chip 110. The lead frame 120 may include a first lead frame 122 and a second lead frame 124 spaced apart from each other to be electrically insulated from each other. The light-emitting chip 110 is mounted on, for example, the first lead frame 122.

The first lead frame 122 may be electrically connected to the light-emitting chip 110 through the first conducting wire 140, and the second lead frame 124 may be electrically connected to the light-emitting chip 110 through the second conducting wire 150. Alternatively, the first lead frame 122 may be electrically connected to a lower surface of the light-emitting chip 110 through a conductive adhesive. A portion of the first lead frame 122 and a portion of the second lead frame 124 may be exposed out of the housing 130 for being electrically connected to an external circuit substrate.

As shown in FIG. 3, the lead frame 120 includes a lead terminal 120a, a light-reflecting layer 120b formed on at least a portion of the lead terminal 120a and a gold plating layer 120c formed on the light-reflecting layer 120b. The gold plating layer 120c has a thickness such that the gold plating layer 120c has a different color from bulk gold. In other words, the gold plating layer 120c is so thin that the gold plating layer 120c loses original color of gold (Au).

The lead terminal 120a corresponds to the chip-mounting portion on which the light-emitting chip 110 is mounted. The lead terminal 120a includes metal of high electrical conductivity and high processability. For example, the lead terminal 120a may include copper is (Cu), or copper alloy including zinc (Zn) or iron (Fe). The lead terminal 120a has a thickness, for example, of about 0.1 to about 1.0 mm. Alternatively, the lead terminal 120a may include other material except metal, such as carbon nanotube (CNT) having high electrical conductivity.

The light-reflecting layer 120b formed on the lead terminal 120a (or base conductive layer) includes a material of high reflectivity for enhancing the reflectivity of the lead frame 120. In order for the light-reflecting layer 120b to operate as a mirror for reflecting light, the reflectivity of the light-reflecting layer 120b should be no lower than about 70%. Therefore, the light-reflecting layer 120b may include silver (Ag), aluminum (Al), platinum (Pt) as shown in Table 1 below. Preferably, the light-reflecting layer 120b may have a higher electrical conductivity and a higher reflectivity than the lead terminal 120a. Therefore, it is preferably that light-reflecting layer 120b includes silver (Ag).

TABLE 1

| Metal | Ag | Al | Pt | W | Mo |
|---|---|---|---|---|---|
| Reflectivity (%) | 97 | 73 | 73 | 62 | 58 |

The light-reflecting layer 120b may be formed on the lead terminal 120a through plating. When the light-reflecting layer 120b is too thin, the reflectivity is lowered since the light-reflecting layer 120b loses its characteristics. On the contrary, when the thickness of the light-reflecting layer 120b increases, reflectivity increases and is saturated but also adds to increased manufacturing cost. Therefore, the thickness of the light-reflecting layer 120b is, preferably, in a range such that the light-reflecting layer 120b operates as the mirror reflecting light and minimizes manufacturing cost. For example, the light-reflecting layer 120b has the thickness of about 1 μm to about 50 μm in order to minimize the manufacturing cost while maintaining reflectivity.

The gold plating layer 120c is formed on a surface of the light-reflecting layer is 120b to prevent corrosion of the light-reflecting layer 120b. Gold (Au) is more resistive to corrosion than a material included in the light-reflecting layer 120b such as silver (Ag). Additionally, gold (Au) has high thermal and electrical conductivity, so that heat generated by the light-emitting chip 110 is easily dissipated and internal electrical resistance of the LED 100 is reduced.

In order to minimize dropping of the reflectivity of the light-reflecting layer 120b, the gold plating layer 120c has a thickness such that the gold plating layer 120c has a different color from bulk gold or the gold plating layer 120c is substantially transparent. For example, the gold plating layer 230 has a thickness of about 0.1 nm to about 50 nm. The gold plating layer 120c may be formed through an electroplating method. In this case, it is very hard to reduce the thickness of the gold plating layer 120c less than about 0.1 nm, and when the thickness of the gold plating layer 120c exceeds about 50 nm, intrinsic color of gold (Au) appears to lower reflectivity of the light-reflecting layer 120b. Therefore, the gold plating layer 120c has a thickness such that the gold plating layer 120c minimizes dropping of reflectivity of the light-reflecting layer 120b and is easily plated. For example, the gold plating layer 120c has a thickness of about 2 nm in order to be easily plated while minimizing dropping of the reflectivity of the light-reflecting layer 120b.

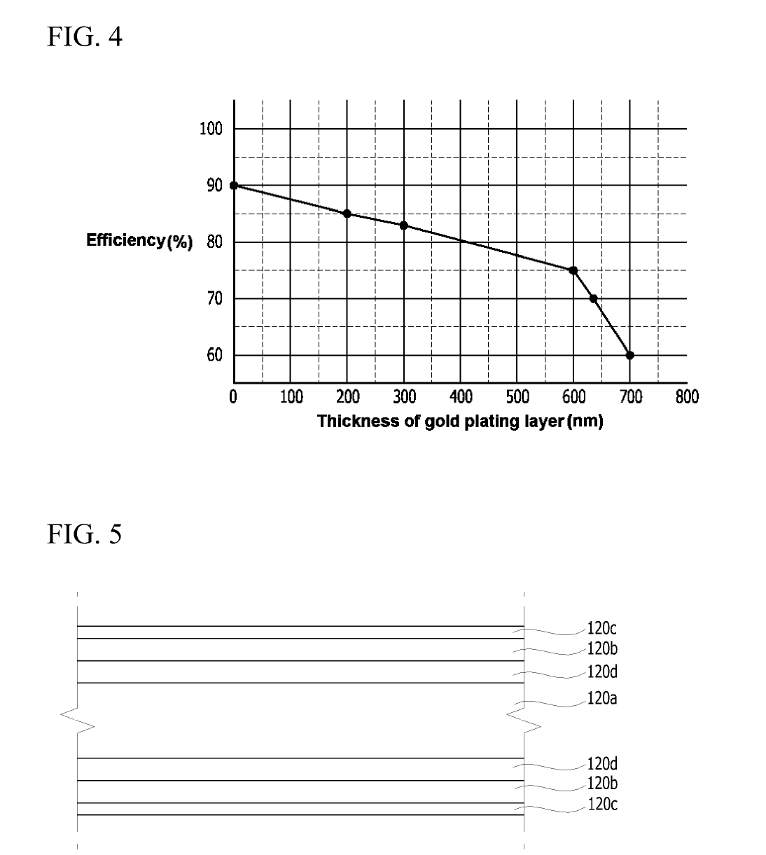

FIG. 4 is a graph showing a relationship between a thickness of a light-reflecting layer 120b including a gold (Au) plating layer 120c compared to efficiency (%). The y-axis represents efficiency of the LED having a silver lead frame 120 with the gold plating layer 120c, wherein the efficiency of an LED having a silver lead frame 120 without a gold plating layer is 120c is 100%. The x-axis represents the thickness of the gold plating layer 120c. In FIG. 4, the thickness of the light-reflecting layer 120b is fixed to be about 3 μm.

Referring to FIG. 3 and FIG. 4, when a gold plating layer 120c that is in a range of about 0.1 nm to about 2 nm thick and is formed on a light-reflecting layer 120b that is about 3 μm thick, the efficiency is about 90%. Keeping the light-reflecting layer 120b constant, when the thickness of the gold plating layer 120c is about 200 nm, the efficiency is about 85%. When the thickness of the gold plating layer 120c is about 300 nm, the efficiency is about 83%. When the thickness of the gold plating layer 120c is about 600 nm, the efficiency is about 75%. When the thickness of the gold plating layer 120c exceeds about 640 nm, which corresponds to the efficiency of about 70%, the efficiency rapidly drops, so that the efficiency becomes about 60% when the thickness of the gold plating layer 120c is about 700 nm.

Therefore, when the gold plating layer 120c formed on the light-reflecting layer 120b is formed to have a thickness in a range of about 0.1 nm, which corresponds to a minimum thickness that can be made through a plating method, to about 50 nm, which corresponds to the efficiency of about 88%, corrosion of the light-reflecting layer 120b may be prevented, while also minimizing a reduction in the reflectivity of the light-reflecting layer 120b.

The light-reflecting layer 120b and the gold plating layer 120c may be formed on both surfaces of the lead terminal 120a or on a surface of the lead terminal 120a, on which the light-emitting chip 110 is mounted. Alternatively, the light-reflecting layer 120b and the gold plating layer 120c may be formed on a portion of the lead terminal 120a, which reflects light emitted by the light-emitting chip 110.

FIG. 5 is a cross-sectional view illustrating a lead frame according to another exemplary embodiment of the present invention. The lead frame in FIG. 5 is substantially the same as the lead frame in FIG. 3 except for a nickel layer. Thus, same reference numerals will be used for the same elements, and any further explanation will be omitted.

Referring to FIG. 5, the lead frame 120 may further include a nickel layer 120d between the lead terminal 120a and the light-reflecting layer 120b. When the lead terminal 120a includes copper (Cu), the light-reflecting layer 120b of silver (Ag) may not be easily plated. Therefore, nickel (Ni) is firstly plated on the lead terminal 120a to form a nickel layer 120d, and then silver (Ag) is plated on the nickel layer 120d to form the light-reflecting layer 120b.

Referring again to FIG. 1 and FIG. 2, the light-emitting chip 110 is mounted on the lead frame 120, and emits light when the light-emitting chip 110 receives electric power through the lead frame 120. For example, the light-emitting chip 110 is mounted on the first lead terminal 122, and the light-emitting chip 110 is electrically connected to the first lead terminal 122 and the second lead terminal 124 through the first conducting wire 140 and the second conducting wire 150, respectively. The light-emitting chip 110 may include semiconductor material, for example, such as gallium nitride, arsenic nitride, or phosphorus nitride. The light-emitting chip 110 may emit light with one of various wavelengths. For example, light-emitting chip 110 may emit blue light, red light, yellow light, green light, or ultraviolet light.

The housing 130 is combined with the lead frame 120 to fix the lead frame 120. That is, the housing 130 is formed such that the housing 130 enwraps at least a portion of the first lead terminal 122 and the second lead terminal 124 to fix the first lead terminal 122 and the second lead terminal 124. The housing 130 may include, for example, polyphthalamide (PPA) resin, etc.

The housing 130 includes an opening portion 132 exposing the light-emitting chip 110 and a portion of the lead frame 120, on which the light-emitting chip 110 is mounted. The is opening portion 132 may have inversed truncated cone shape with increasing diameter along an upper direction. Therefore, a wall of the opening portion 132 is slant, and a light reflecting material may be formed on the wall of the opening portion 132.

The encapsulant 160 fills up the opening portion 132 of the housing 130 to cover the light-emitting chip 110. The encapsulant 160 protects the light-emitting chip 110, and includes for example, transparent epoxy resin or silicone resin. The encapsulant 160 may include phosphor 162 distributed therein to convert wavelength of light emitted by the light-emitting chip 110. For example, the encapsulant 160 may include at least one of red, green, and blue phosphor to generate colored light or white light.

The LED 100 may generate white light by using the light-emitting chip 110 and the phosphor 162.

For example, the light-emitting chip 110 emits blue light, and the phosphor 162 may convert a portion of the blue light emitted by the light-emitting chip 110 into yellow light. In detail, the light-emitting chip 110 may include, for example, InGaN series semiconductor, which emits blue light in a range of about 430 nm to about 470 nm, and the yellow phosphor is excited by the blue light emitted by the light-emitting chip 110 to emit yellow light. The yellow phosphor include, for example, yttrium aluminum garnet (Y3Al5O12; YAG) series, silicate series or TAG series. Therefore, the LED 100 generates white light in which a portion of the blue light generated by the light-emitting chip 110 and yellow light converted from a remaining portion of the blue light are mixed.

Alternatively, the light-emitting chip 110 emits blue light, and red and green phosphors of the phosphor 162 may convert a portion of the blue light emitted by the light-emitting chip 110 into red light and green light, respectively. The red phosphor may include is inorganic compound with a crystal structure that is similar to, for example, SrS:Eu, Sr,CaS:Eu, CaS:Eu, Sr,CaGeS:Eu and CaAlSiN3 or solid solution. The green phosphor may include, for example, SrGa2S4:Eu and Ba,Sr,Ca2SiO4:Eu, etc. Therefore, the LED 100 generates white light in which a portion of the blue light generated by the light-emitting chip 110, red light converted by the red phosphor from a first remaining portion of the blue light, and green light converted by the green phosphor from a second remaining portion of the blue light are mixed. As described above, when white light is generated by the light-emitting chip 110 emitting blue light, the red phosphor and the green phosphor, the color reproducibility is improved to be about 90˜110 by maximum 20%, comparing the white light generated by using light-emitting chip 110 emitting blue light and yellow phosphor, of which color reproducibility is about 85.

Alternatively, the LED 100 may include two light-emitting chips 110 emitting different colors from each other, and a phosphor 162. For example, the two light-emitting chips 110 may emit blue light and red light, respectively, and the phosphor 162 may convert a portion of the blue light into green light. Alternatively, the two light-emitting chips 110 may emit blue light and green light, respectively, and the phosphor 162 may convert a portion of the blue light or a portion of the green light into red light.

According to the LED 100 described above, the light emitted from the light-emitting chip 110 or the phosphor 162 to advance downward is reflected by the lead frame 120 to advance upward. In this case, by using the light-reflecting layer 120b of silver (Ag) and the gold plating layer 120c formed on the light-reflecting layer 120b, the lead frame 120 is prevented from being corroded and discolored, while minimizing a reduction in reflectivity.

The lead frame 120 of the present invention may be applied to various types of packages, such as a top-view package, a side-view package, a lamp-type package, a chip-type is package, etc.

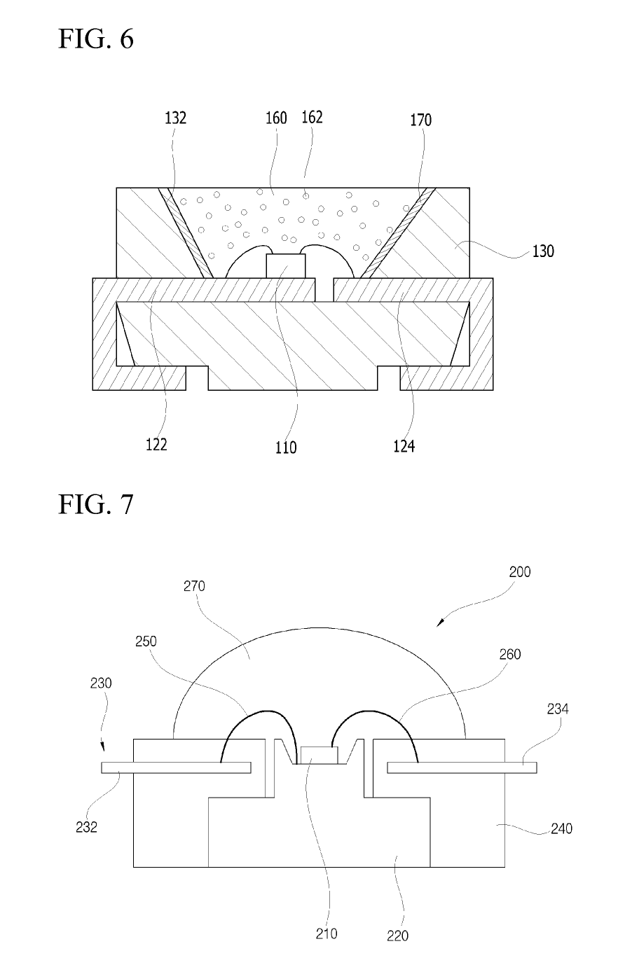

FIG. 6 is a cross-sectional view illustrating an LED according to still another exemplary embodiment of the present invention. The LED in FIG. 6 is substantially the same as the LED in FIG. 2 except for a reflector. Thus, same reference numerals will be used for the same elements, and any further explanation will be omitted.

Referring to FIG. 6, the LED according to still another exemplary embodiment of the present invention further includes a reflector 170 formed on a wall of the opening portion 132 of the housing 130. The reflector 170 reflects light generated by the light-emitting chip 110 to improve efficiency of the LED. The reflector 170 includes metal of high reflectivity similar to the lead frame 120. Therefore, the reflector 170 may include a gold plating layer 120c having a thickness such that the gold plating layer 120c has a different color from bulk gold (or intrinsic color of gold) to prevent corrosion and discoloring of the light-reflecting layer 120b, as shown in FIG. 3. Furthermore, the reflector 170 may also include the nickel layer 120d.

FIG. 7 is a cross-sectional view illustrating an LED according to still another exemplary embodiment of the present invention.

Referring to FIG. 7, an LED 200 according to still another exemplary embodiment of the present invention includes a light-emitting chip 210, a slug 220 corresponding to the chip-mounting portion on which the light-emitting chip 210 is mounted, a lead frame 230 to apply electrical power to the light-emitting chip 110, and a housing 240 fixing the slug 220 and the lead frame 230. The LED 200 may further include a first conducting wire 250 and a second conducting wire 260 electrically connecting the light-emitting chip 210 to the lead frame 230, and an encapsulant 270 covering the light-emitting chip 210.

The slug 220 dissipates heat generated by the light-emitting chip 210. The slug 220 may be disposed at an internal center portion of the housing 240. The light-emitting chip 210 is mounted on an upper portion of the slug 220, and a lower portion of the slug 220 is exposed out of the housing 240.

In order for that the slug 220 is prevented from being corroded and discolored while minimizing a reduction in reflectivity, a light-reflecting layer and a gold plating layer may be formed on at least a portion of the slug 220 similar to the lead frame 120 in FIG. 3. The structure of the light-reflecting layer and the gold plating layer is substantially the same as that described referring to FIG. 3. Therefore, any further explanation will be omitted.

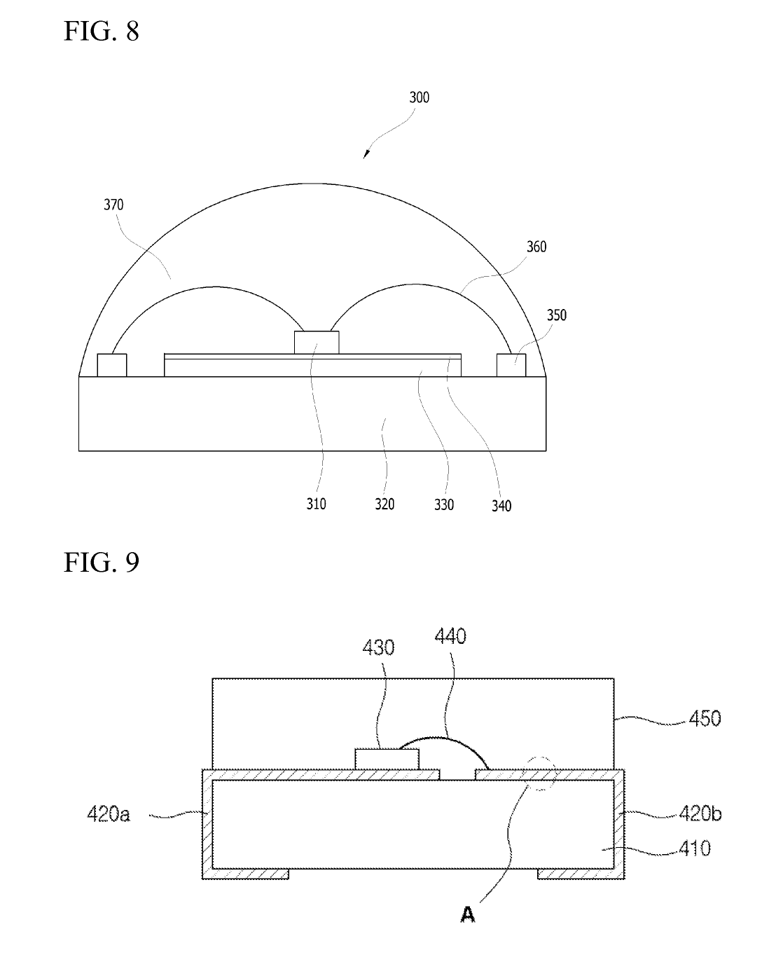

FIG. 8 is a cross-sectional view illustrating an LED according to still another exemplary embodiment of the present invention.

Referring to FIG. 8, an LED 300 according to still another exemplary embodiment of the present invention includes a light-emitting chip 310, a substrate 320 corresponding to the chip-mounting portion on which the light-emitting chip 310 is mounted, a light-reflecting layer 330 formed on at least a portion of the substrate 320 and a gold plating layer 340 formed on the light-reflecting layer 330. The LED 300 may further include at least one lead frame 350 applying electric power to the light-emitting chip 310, at least one conducting wire 360 electrically connecting the light-emitting chip 310 to the lead frame 350, and an encapsulant 370 covering the light-emitting chip 310 and the conducting wire 360.

The substrate 320 supports the light-emitting chip 310 and applies electrical power to the light-emitting chip 310. Various substrates such as a printed circuit board, a ceramic substrate, a carbon nanotube (CNT) substrate may be employed as the substrate 320.

A light-reflecting layer 330 reflecting light emitted from the light-emitting chip 310 and a gold plating layer 340 preventing the light-reflecting layer 330 from being corroded, are formed on at least a portion of the substrate 320. The structure of the light-reflecting layer 330 and the gold plating layer 340 is substantially the same as that in FIG. 3. Thus, any further explanation will be omitted.

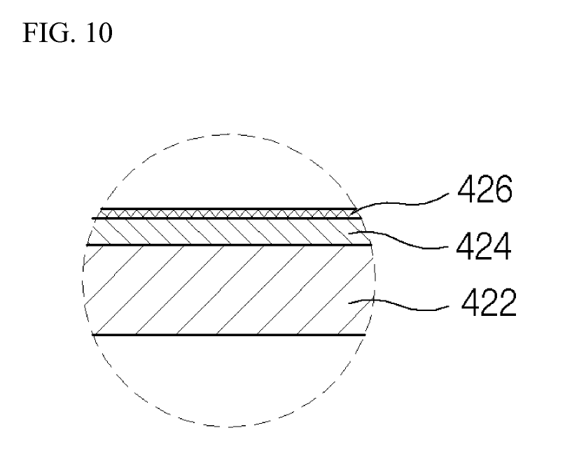

FIG. 9 is a cross-sectional view illustrating an LED according to still another exemplary embodiment of the present invention, and FIG. 10 is an enlarged view illustrating the portion ‘A’ in FIG. 9.

Referring to FIG. 9 and FIG. 10, an LED according to still another exemplary embodiment of the present invention includes a substrate 410, a first lead frame 420a, a second lead frame 420b, and a light-emitting chip 430. The first lead frame 420a and the second lead frame 420b are formed on the substrate 410 and spaced apart from each other, and a gold plating layer 426 is formed on at least a portion of the first lead frame 420a and the second lead frame 420b. The light-emitting chip 430 is electrically connected to the first lead frame 420a and the second lead frame 420b. The LED may further include a molding part 450 molding the light-emitting chip 430 and a portion of the first lead frame 420a and the second lead frame 420b.

The substrate 410 supports the light-emitting chip 430, the first lead frame 420a, and the second lead frame 420b. A printed circuit board, a ceramic substrate, a carbon nanotube (CNT) substrate, etc., may be employed as the substrate 410.

The first lead frame 420a and the second lead frame 420b apply electric power to the light-emitting chip 430. A light-reflecting layer 424 may be formed on at least a portion of the first lead frame 420a and the second lead frame 420b, and a gold plating layer 426 is formed on the light-reflecting layer 424. The gold plating layer 426 has a thickness such that the gold plating layer 426 has a different color from bulk gold (or intrinsic color of gold) to prevent corrosion and discoloring of the light-reflecting layer 424, as shown in FIG. 3. The structure of the lead terminal 422, the light-reflecting layer 424, and the gold plating layer 426 are substantially the same as in FIG. 3. Thus, any further explanation will be omitted.

The molding part 450 molds the light-emitting chip 430 and fixes the conducting wire 440 electrically connecting the light-emitting chip 430 to the second lead frame 420b. The molding part 450 includes a material such as epoxy resin or silicone resin. Furthermore, the molding part 450 may be formed to have a convex lens shape to focus light generated by the light-emitting chip 430.

The molding part 450 may include light-diffusing particles distributed therein. The light-diffusing particles diffuse light generated by the light-emitting chip 430 to provide more uniform light. For example, barium titanate, titanium oxide, aluminum oxide, silicon oxide, etc. may be employed as the light-diffusing particles. The molding part 450 may further include a phosphor. The phosphor receives a first light generated by the light-emitting chip 430 to emit a second light having different a wavelength from the first light. The phosphor includes a host lattice and active ions injected into a proper position.

As described above, when a light-reflecting layer of high reflectivity and a thin gold plating layer are formed on the light-emitting chip, corrosion of the light-reflecting layer and the chip-mounting portion, such as the lead terminal, the slug, the printed circuit board, the ceramic substrate, the CNT substrate, etc., may be prevented, while also minimizing a reduction in the reflectivity of the light-reflecting layer.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting device (LED), comprising:
a light-emitting chip to emit light;
a chip-mounting portion on which the light-emitting chip is disposed;
a light-reflecting layer disposed on at least a portion of the chip-mounting portion; and
a gold plating layer disposed on at least a portion of the light-reflecting layer, the gold plating layer having a thickness such that the gold plating layer has a different color from a color of gold (Au).

2. The LED of claim 1, wherein the light-reflecting layer comprises a metal having a reflectivity not lower than 70%.

3. The LED of claim 2, wherein the light-reflecting layer comprises at least one of silver (Ag), platinum (Pt), and aluminum (Al).

4. The LED of claim 1, wherein the gold plating layer is 0.1 nm to 50 nm thick.

5. The LED of claim 1, wherein the chip-mounting portion comprises one of a lead terminal, a slug, a printed circuit board, a ceramic substrate, and a carbon nanotube substrate.

6. The LED of claim 1, further comprising:
a housing fixing the chip-mounting portion, the housing having an opening portion to expose the light-emitting chip; and
a reflector disposed on the opening portion of the housing.

7. The LED of claim 6, wherein the reflector comprises a gold plating layer.

8. The LED of claim 7, wherein the gold plating layer of the reflector has a thickness such that the gold plating layer has a different color from a color of gold (Au).

9. The LED of claim 6, wherein the opening portion has an inverse cone shape, such that the opening portion increases in diameter along a vertical direction away from the light-emitting chip.

10. The LED of claim 6, further comprising an encapsulant disposed over the light-emitting chip.

11. The LED of claim 10, wherein the encapsulant comprises a phosphor.

12. A lead frame, comprising:
a lead terminal;
a light-reflecting layer disposed on at least a portion of the lead terminal; and
a gold plating layer disposed on at least a portion of the light-reflecting layer, the gold plating layer having a thickness such that the gold plating layer has a different color from a color of gold (Au).

13. The lead frame of claim 12, wherein the light-reflecting layer comprises a metal having a reflectivity not lower than 70%.

14. The lead frame of claim 12, wherein the light-reflecting layer comprises at least one of silver (Ag), platinum (Pt), and aluminum (Al).

15. The lead frame of claim 12, wherein the gold plating layer is 0.1 nm to 50 nm thick.

16. The lead frame of claim 12, further comprising a nickel layer disposed between the lead terminal and the light-reflecting layer.

17. The lead frame of claim 12, wherein the light-reflecting layer has a higher electrical conductivity and a higher reflectivity than the lead terminal.

18. A light emitting device (LED), comprising:
a light-emitting chip to emit light;
a lead terminal on which the light-emitting chip is disposed;
a light-reflecting layer disposed between the lead terminal and the light-emitting chip;
a gold plating layer disposed on the light-reflecting layer, the gold plating layer having a thickness such that the gold plating layer has a different color from a color of gold (Au); and
wherein the light-reflecting layer has a higher electrical conductivity and a higher reflectivity than the lead terminal.

19. The LED of claim 18, wherein the gold plating layer is 0.1 nm to 50 nm thick.

20. The LED of claim 18, further comprising an encapsulant disposed over the light-emitting chip.
